(19) United States
(12) Patent Application Publication
(10) Pub. No.: US 2018/0197907 A1
(43) Pub. Date: Jul. 12, 2018

(54) SOLID-STATE IMAGING DEVICE AND IMAGING SYSTEM

(71) Applicant: CANON KABUSHIKI KAISHA, Tokyo (JP)

(72) Inventors: Yoichi Wada, Yokohama-shi (JP); Yoichiro Handa, Tokyo (JP); Tetsuya Itano, Sagamihara-shi (JP)

(21) Appl. No.: 15/854,304

(22) Filed: Dec. 26, 2017

(30) Foreign Application Priority Data
Jan. 10, 2017 (JP) 2017-001667

(51) Int. Cl. H01L 27/146; H04N 9/04; H04N 5/3745; H04N 5/357

(52) U.S. Cl. CPC H01L 27/14612; H04N 9/045; H01L 27/14603; H04N 5/3577; H04N 5/3745

(57) ABSTRACT

A disclosed embodiment includes a first pixel including a photoelectric converter and a first transistor that transfers charges generated in the photoelectric converter to a first node, wherein the first pixel outputs a first signal based on a voltage of the first node, a second pixel including a second transistor that supplies a constant voltage to a second node, wherein the second pixel outputs a second signal based on a voltage of the second node, and a control line connected to the first transistor and the second transistor, wherein a capacitance value of a capacitance component coupled to the second node is greater than a capacitance value of a capacitance component coupled to the first node.

### BACKGROUND OF THE INVENTION

### Field of the Invention

The present invention relates to a solid-state imaging device and an imaging system.

### Description of the Related Art

In recent years, there is a demand for reduction in size and improvement of the reliability of a solid-state imaging device. In particular, in vehicle applications or the like, the operating environment is severe and safety measures are very important, and therefore an imaging system having a failure detection function is demanded for supporting functional safety. This also requires to embed a failure detection mechanism into a solid-state imaging device.

Japanese Patent No. 4818112 discloses a solid-state imaging device that, via at least a part of a transmission path through which a signal from a pixel which generates a signal in accordance with the amount of an incident light is transmitted, outputs a signal from a pixel which generates a reference signal and, based on the output reference signal, performs failure detection for an abnormality of the transmission path or the like.

When there is a pixel defect in pixels which generate a reference signal, however, a predetermined reference signal cannot be output, which may make it impossible to perform failure detection. Further, even when the pixel defect level of the pixel which generates the reference signal is small, an output signal is amplified and thus exceeds the determination threshold in failure detection, which may make it impossible to perform failure detection of the transmission path.

### SUMMARY OF THE INVENTION

An object of the present invention is to provide a solid-state imaging device and an imaging system that can reduce a failure determination error due to the output variation of pixels used for failure detection.

According to an aspect of the present invention, there is provided a solid-state imaging device including a first pixel including a photoelectric converter and a first transistor that transfers charges generated in the photoelectric converter to a first node, wherein the first pixel outputs a first signal based on a voltage of the first node, a second pixel including a second transistor that supplies a constant voltage to a second node, wherein the second pixel outputs a second signal based on a voltage of the second node, and a control line connected to the first transistor and the second transistor, wherein a capacitance value of a capacitance component coupled to the second node is greater than a capacitance value of a capacitance component coupled to the first node.

According to another aspect of the present invention, there is provided a solid-state imaging device including a first pixel including a photoelectric converter and a first transistor that transfers charges generated in the photoelectric converter to a first node, wherein the first pixel outputs a first signal based on a voltage of the first node, a second pixel including a second transistor that supplies a constant voltage to a second node, wherein the second pixel outputs a second signal based on a voltage of the second node, a control line connected to the first transistor and the second transistor, a first amplifier unit that amplifies the first signal, and a second amplifier unit that amplifies the second signal, wherein, in a period in which the first signal and the second signal are output, an amplification factor of the second amplifier unit is less than an amplification factor of the first amplifier unit.

Further features of the present invention will become apparent from the following description of exemplary embodiments with reference to the attached drawings.

### BRIEF DESCRIPTION OF THE DRAWINGS

FIG. 1 is a diagram illustrating a general configuration of a solid-state imaging device according to a first embodiment of the present invention.

FIG. 2 is an equivalent circuit diagram of pixels of the solid-state imaging device according to the first embodiment of the present invention.

FIG. 3, FIG. 4 and FIG. 5 are diagrams illustrating planar layouts of the pixels of the solid-state imaging device according to the first embodiment of the present invention.

FIG. 6 is a diagram illustrating a failure detection method of the solid-state imaging device according to the first embodiment of the present invention.

FIG. 7 is a diagram illustrating a general configuration of a solid-state imaging device according to a second embodiment of the present invention.

FIG. 8 is a diagram illustrating a failure detection method of the solid-state imaging device according to the second embodiment of the present invention.

FIG. 9 is a timing chart illustrating a method of driving a solid-state imaging device according to a third embodiment of the present invention.

FIG. 10 is an equivalent circuit diagram of pixels of the solid-state imaging device according to a fourth embodiment of the present invention.

FIG. 11 is a diagram illustrating a planar layout of the pixels of the solid-state imaging device according to the fourth embodiment of the present invention.

FIG. 12 is a schematic diagram illustrating an example configuration of an imaging system according to a fifth embodiment of the present invention.

FIG. 13A, FIG. 13B and FIG. 13C are schematic diagrams illustrating an example configuration of a movable object according to the fifth embodiment of the present invention.

FIG. 14 is a flow diagram illustrating an operation of the imaging system according to the fifth embodiment of the present invention.

### DESCRIPTION OF THE EMBODIMENTS

Preferred embodiments of the present invention will now be described in detail in accordance with the accompanying drawings.

### First Embodiment

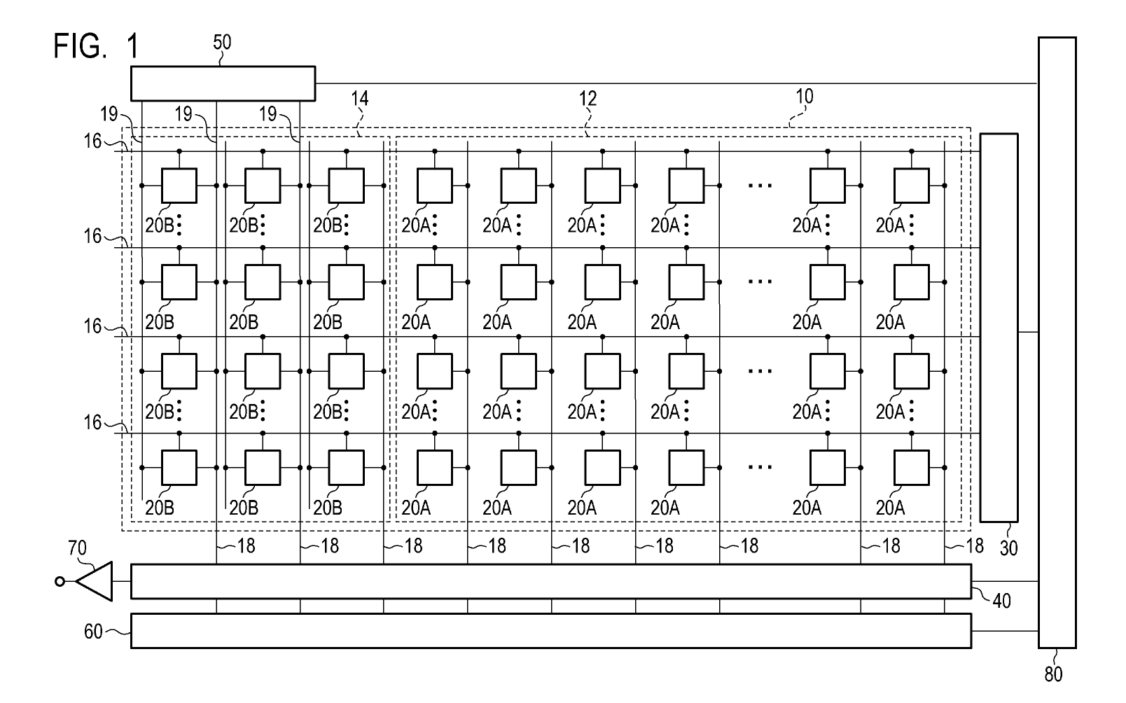

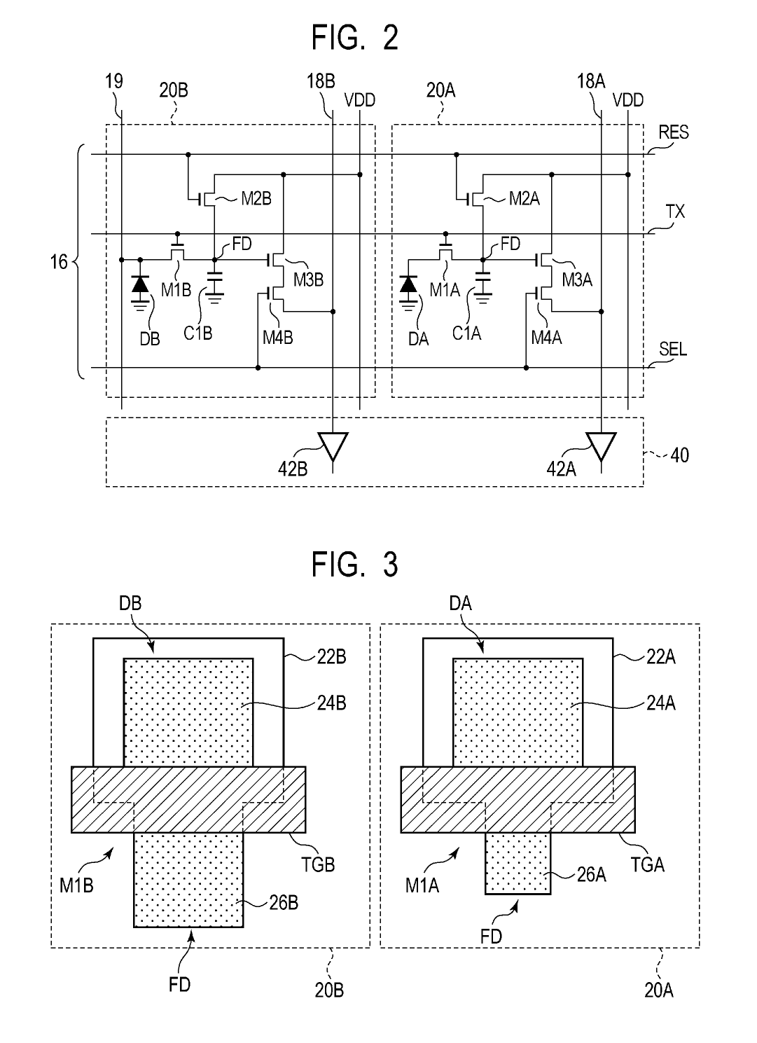

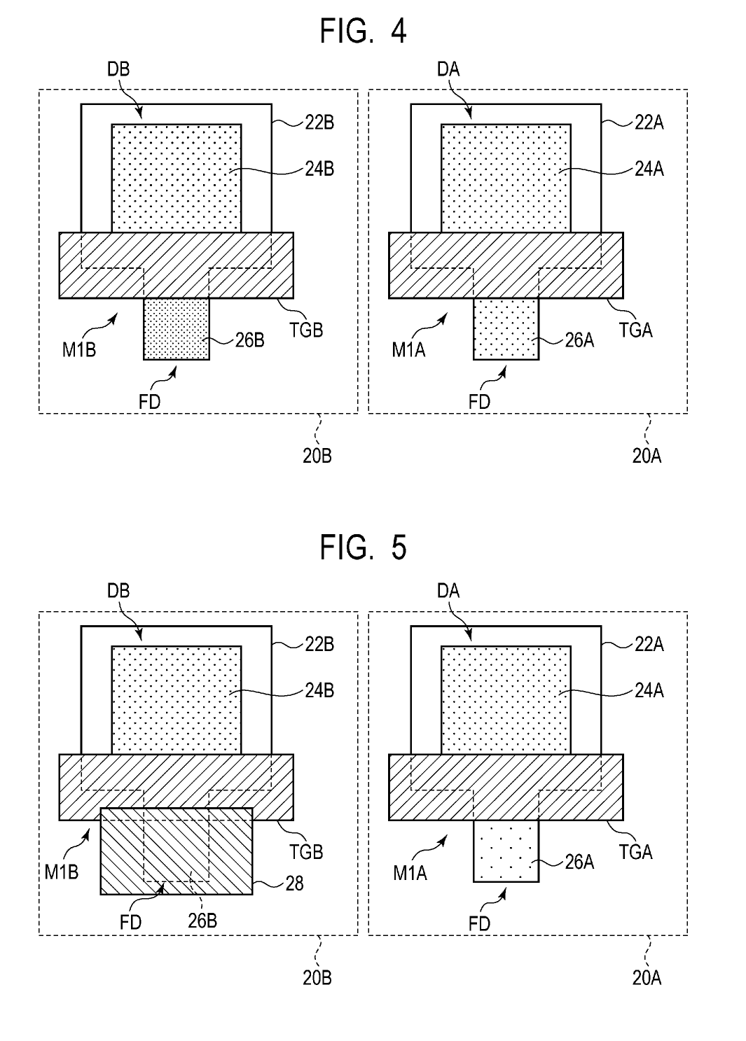

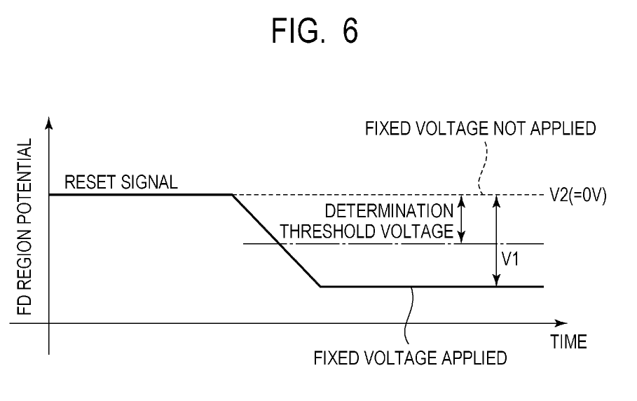

A solid-state imaging device according to a first embodiment of the present invention will be described with reference to FIG. 1 to FIG. 6. FIG. 1 is a diagram illustrating a general configuration of the solid-state imaging device according to the present embodiment. FIG. 2 is an equivalent circuit diagram of pixels of the solid-state imaging device according to the present embodiment. FIG. 3 to FIG. 5 are diagrams illustrating planar layouts of the pixels of the solid-state imaging device according to the present embodiment. FIG. 6 is a diagram illustrating a failure detection method of the solid-state imaging device according to the present embodiment.

First, the solid-state imaging device according to the present embodiment will be described by using FIG. 1 to FIG. 5.

As illustrated in FIG. 1, a solid-state imaging device 100 according to the present embodiment includes a pixel array unit 10, a vertical scanning circuit 30, a column circuit 40, a voltage supply unit 50, a horizontal scanning circuit 60, an output circuit 70, and a control unit 80.

The pixel array unit 10 includes a first region 12 and a second region 14. In the first region 12, a plurality of pixels 20A used for image acquisition are arranged over a plurality of rows and a plurality of columns. In the second region 14, a plurality of pixels 20B used for failure detection are arranged over a plurality of rows and a plurality of columns. The first region 12 and the second region 14 are arranged neighboring in the row direction (the horizontal direction in FIG. 1), that is, while rows on which the pixels 20A are arranged and rows on which the pixels 20B are arranged are the same as each other, columns on which the pixels 20A are arranged and columns on which the pixels 20B are arranged are different from each other. The number of rows and columns forming each region is not limited in particular.

On each row of the pixel array unit 10, a pixel control line 16 extending in the row direction is arranged. The pixel control line 16 on each row serves as a signal line common to the pixels 20A and 20B belonging to the corresponding row. The pixel control lines 16 are connected to the vertical scanning circuit 30.

On each column of the pixel array unit 10, a vertical output line 18 extending in the column direction is arranged. The vertical output line 18 on each column serves as a signal line common to the pixels 20A and 20B belonging to the corresponding column. The vertical output lines 18 are connected to the column circuit 40. Note that, in the present specification, each vertical output line connected to the pixels 20A may be denoted as a vertical output line 18A, and each vertical output line connected to the pixels 20B may be denoted as a vertical output line 18B.

On each column in the second region 14 of the pixel array unit 10, a voltage supply line 19 extending in the column direction is arranged. The voltage supply line 19 on each column serves as a signal line common to the pixels 20B belonging to the corresponding column. The voltage supply lines 19 are connected to the voltage supply unit 50. Note that the voltage supply line 19 on each column may include a plurality of voltage supply lines connected to the pixels 20B that are different from each other. For example, when the pixels 20B included in one column are divided into two groups, the voltage supply lines 19 may include voltage supply lines connected to the pixels 20B of one of the groups and voltage supply lines connected to the other group. Further, the voltage supply lines 19 may be formed of signal lines arranged in the row direction.

The vertical scanning circuit 30 supplies predetermined control signals used for driving the pixels 20A and 20B via the pixel control lines 16. Some logic circuits such as a shift resistor or an address decoder may be used for the vertical scanning circuit 30. Although the pixel control line 16 on each row is depicted as a single signal line in FIG. 1, multiple signal lines may be included in the actual implementation. The pixels 20A and 20B on a row selected by the vertical scanning circuit 30 operate to output signals to the corresponding vertical output lines 18 at the same time.

The column circuit 40 has a plurality of column amplifier circuits 42 corresponding to the number of columns of the pixel array unit 10 (see FIG. 2). The column amplifier circuits 42 are connected to the vertical output lines 18 on the respective columns. The column circuit 40 amplifies each pixel signal that is output to the vertical output line 18 on each column by using the column amplifier circuit 42 on each column. Further, the column circuit 40 performs, on each pixel signal that is output from the pixel 20A, a correlated double sampling (CDS) process based on a reset signal and a photoelectric conversion signal. The column circuit 40 performs, on each pixel signal that is output from the pixel 20B, a CDS process based on a reset signal and a signal obtained when a voltage is input from the voltage supply line 19. Note that, in the present specification, each column amplifier circuit connected to the vertical output line 18A may be denoted as a column amplifier circuit 42A and each column amplifier circuit connected to the vertical output line 18B may be denoted as a column amplifier circuit 42B.

The horizontal scanning circuit 60 supplies, to the column circuit 40, control signals for transferring pixel signals processed in the column circuit 40 to the output circuit 70 sequentially on a column basis.

The output circuit 70 is formed of a buffer amplifier, a differential amplifier, or the like and outputs a pixel signal transferred from the column circuit 40 to a signal processing unit (not illustrated) outside the solid-state imaging device 100. Note that an analog-to-digital (AD) conversion unit may be provided to the column circuit 40 or the output circuit 70 to output a digital image signal to the outside.

The voltage supply unit 50 is a power source circuit that supplies a predetermined voltage to the pixels 20B via the voltage supply lines 19. When the voltage supply line 19 on each column includes a plurality of voltage supply lines, these plurality of voltage supply lines may be configured to be supplied with voltages different from each other.

The control unit 80 is a circuit unit that supplies control signals used for controlling their operations or timings to the vertical scanning circuit 30, the column circuit 40, the voltage supply unit 50, and the horizontal scanning circuit 60. A part of or all of the control signals supplied to the vertical scanning circuit 30, the column circuit 40, the voltage supply unit 50, and the horizontal scanning circuit 60 may be supplied from the outside of the solid-state imaging device 100.

FIG. 2 is an equivalent circuit diagram illustrating an example configuration of the pixels 20A of the first region 12 and the pixels 20B of the second region 14. In FIG. 2, from the plurality of pixels 20A and the plurality of pixels 20B of the pixel array unit 10, one of the pixels 20A and one of the pixels 20B which belong to the same row are selected and depicted.

The pixel 20A includes a photoelectric converter DA, a transfer transistor M1A, a reset transistor M2A, an amplifier transistor M3A, and a select transistor M4A. The photoelectric converter DA is a photoelectric conversion element, such as a photodiode, for example. The anode of the photodiode of the photoelectric converter DA is connected to a reference voltage terminal GND, and the cathode thereof is connected to the source of the transfer transistor M1A. The drain of the transfer transistor M1A is connected to the source of the reset transistor M2A and the gate of the amplifier transistor M3A. The connection node of the drain of the transfer transistor M1A, the source of the reset transistor M2A, and the gate of the amplifier transistor M3A forms a so-called floating diffusion (FD) region. In FIG. 2, the FD region is denoted as “FD.” The parasitic capacitance component coupled to the FD region (FD capacitance value: CfdA) which is formed between the FD region and an interconnection or another FD region has a function as a charge holding portion. FIG. 2 depicts this capacitance component as a capacitor C1A connected to the FD region. The drain of the reset transistor M2A and the drain of the amplifier transistor M3A are connected to a power source voltage line VDD. The source of the amplifier transistor M3A is connected to the drain of the select transistor M4A. The source of the select transistor M4A is connected to the vertical output line 18A.

The pixel 20B includes a photoelectric converter DB, a transfer transistor M1B, a reset transistor M2B, an amplifier transistor M3B, and a select transistor M4B. The photoelectric converter DB is a photoelectric conversion element, such as a photodiode, for example. The anode of the photodiode of the photoelectric converter DB is connected to the reference voltage terminal GND, and the cathode thereof is connected to the source of the transfer transistor M1B. The connection node between the photoelectric converter DB and the transfer transistor M1B is connected with the voltage supply line 19. The drain of the transfer transistor M1B is connected to the source of the reset transistor M2B and the gate of the amplifier transistor M3B. The connection node of the drain of the transfer transistor M1B, the source of the reset transistor M2B, and the gate of the amplifier transistor M3B forms a FD region. In FIG. 2, the parasitic capacitance component coupled to the FD region (FD capacitance value: CfdB) which is formed between the FD region and an interconnection or another FD region is illustrated as a capacitor C1B. The drain of the reset transistor M2B and the drain of the amplifier transistor M3B are connected to the power source voltage line VDD. The source of the amplifier transistor M3B is connected to the drain of the select transistor M4B. The source of the select transistor M4B is connected to the vertical output line 18B.

As described above, the pixel 20B is the same as the pixel 20A in view of the circuit configuration except that the voltage supply line 19 is connected to the connection node between the photoelectric converter DB and the transfer transistor M1B. Note that the second region, that is, the pixel 20B is covered with a light-shielding film (not illustrated). The pixel 20B is not necessarily required to have the photoelectric converter DB. In this case in particular, because the transfer transistor M1B of the pixel 20B is driven simultaneously with the transfer transistor M1A of the pixel 20A although not necessarily intended to transfer charges, the transfer transistor M1B is denoted as “transfer transistor” for the purpose of illustration.

In the case of the pixel configuration of FIG. 2, the pixel control lines 16 arranged on each row include signal lines TX, RES, and SEL. The signal line TX is connected to the gates of the transfer transistors M1A of the pixels 20A and the gates of the transfer transistors M1B of the pixels 20B belonging to the corresponding row, respectively. The signal line RES is connected to the gates of the reset transistors M2A of the pixels 20A and the gates of the reset transistors M2B of the pixels 20B belonging to the corresponding row, respectively. The signal line SEL is connected to the gates of the select transistors M4A of the pixels 20A and the gates of the select transistors M4B of the pixels 20B belonging to the corresponding row, respectively.

A control signal ϕTX that is a drive pulse for controlling the transfer transistors M1A and M1B is output to the signal line TX from the vertical scanning circuit 30. A control signal ϕRES that is a drive pulse for controlling the reset transistors M2A and M2B is output to the signal line RES from the vertical scanning circuit 30. A control signal SEL that is a drive pulse for controlling the select transistors M4A and M4B is output to the signal line SEL from the vertical scanning circuit 30. Common control signals ϕTX, ϕRES, and SEL are supplied from the vertical scanning circuit 30 to the pixels 20A and 20B on the same row. When each transistor is formed of an n-channel transistor, a high level control signal supplied from the vertical scanning circuit 30 causes the corresponding transistor to be turned on, and a low level control signal supplied from the vertical scanning circuit 30 causes the corresponding transistor to be turned off.

The photoelectric converter DA converts (photoelectrically converts) an incident light into an amount of charges in accordance with the light amount thereof and accumulates the generated charges. When turned on, the transfer transistor M1A of the pixel 20A transfers the charges of the photoelectric converter DA to the FD region. This causes the FD region to have a voltage in accordance with the amount of charges transferred from the photoelectric converter DA through charge-to-voltage conversion by the FD capacitance CfdA. The amplifier transistor M3A is configured such that the voltage VDD is supplied to the drain thereof and a bias current is supplied to the source thereof from a current source (not illustrated) via the select transistor M4A, which forms an amplifier unit (source follower circuit) whose gate is the input node. This causes the amplifier transistor M3A to output a signal based on the voltage of the FD region to the vertical output line 18A via the select transistor M4A. When turned on, the transfer transistor M1B of the pixel 20B applies the voltage supplied from the voltage supply line 19 to the FD region. The amplifier transistor M3B is configured such that the voltage VDD is supplied to the drain thereof and a bias current is supplied to the source thereof from a current source (not illustrated) via the select transistor M4B, which forms an amplifier unit (source follower circuit) whose gate is the input node. This causes the amplifier transistor M3B to output a signal based on the voltage of the FD region to the vertical output line 18B via the select transistor M4B. When turned on, the reset transistors M2A and M2B reset the FD regions to a voltage in accordance with the voltage VDD.

In the solid-state imaging device according to the present embodiment, the amplification factor of a signal based on the amount of charges held in the FD region of the pixel 20A is different from the amplification factor of a signal based on the amount of charges held in the FD region of the pixel 20B. In the present embodiment, the FD capacitance value CfdA of the pixel 20A and the FD capacitance value CfdB of the pixel 20B are set to different values, and thereby the amplification factors of the signals thereof are different from each other. Specifically, in the solid-state imaging device according to the present embodiment, the FD capacitance value CfdA and the FD capacitance value CfdB have a relationship of:

CfdA<CfdB.

As a method of differentiating the FD capacitance value CfdA of the pixel 20A and the FD capacitance value CfdB of the pixel 20B from each other, there are methods as illustrated in FIG. 3 to FIG. 5, for example, though not limited thereto. FIG. 3 to FIG. 5 are diagrams illustrating planar layouts of the pixel 20A and the pixel 20B. FIG. 3 to FIG. 5 depict only the photoelectric converter DA and the transfer transistor M1A out of the components of the pixel 20A. Further, FIG. 3 to FIG. 5 depict only the photoelectric converter DB and the transfer transistor M1B out of the components of the pixel 20B.

The pixel 20A includes an active region 22A provided in a semiconductor substrate and semiconductor regions 24A and 26A of the same conductivity type (for example, n-type) provided spaced apart from each other inside the active region 22A. The semiconductor region 24A is an impurity diffused region that forms the photoelectric converter DA and the source of the transfer transistor M1A. The semiconductor region 26A is an impurity diffused region forming the FD region and the drain of the transfer transistor M1A. A gate electrode TGA of the transfer transistor M1A is provided between the semiconductor regions 24A and 26A above the semiconductor substrate.

Similarly, the pixel 20B includes an active region 22B provided in a semiconductor substrate and semiconductor regions 24B and 26B of the same conductivity type (for example, n-type) provided spaced apart from each other inside the active region 22B. The semiconductor region 24B is an impurity diffused region that forms the photoelectric converter DB and the source of the transfer transistor M1B. The semiconductor region 26B is an impurity diffused region forming the FD region and the drain of the transfer transistor M1B. A gate electrode TGB of the transfer transistor M1B is provided between the semiconductor regions 24B and 26B above the semiconductor substrate.

In the example of FIG. 3, the area of the semiconductor region 26B forming the FD region of the pixel 20B is larger than the area of the semiconductor region 26A of the FD region of the pixel 20A. This allows the FD capacitance value CfdB to be greater than the FD capacitance value CfdA.

In the example of FIG. 4, the impurity concentration of the semiconductor region 26B forming the FD region of the pixel 20B is higher than the impurity concentration of the semiconductor region 26A forming the FD region of the pixel 20A. The higher impurity concentration results in a narrower width of the depletion layer expanding in the direction of semiconductor region 26B at the p-n junction formed between the semiconductor region 26B and the well and therefore allows for an increased p-n junction capacitance. Therefore, with the impurity concentration of the semiconductor region 26B forming the FD region of the pixel 20B being higher than the impurity concentration of the semiconductor region 26A forming the FD region of the pixel 20A, it is possible to have the FD capacitance value CfdB greater than the FD capacitance value CfdA.

Note that, while the area of the semiconductor region 26A and the area of the semiconductor region 26B are the same as each other in the example of FIG. 4, they are not necessarily required to be the same as long as the relationship between the FD capacitance value CfdA and the FD capacitance value CfdB is maintained. For example, in a similar manner to the example of FIG. 3, the area of the semiconductor region 26A may be greater than the area of the semiconductor region 26B.

In the example of FIG. 5, an additional capacitor interconnection 28 is provided over the semiconductor region 26B forming the FD region of the pixel 20B with an insulating layer (not illustrated) interposed therebetween. The additional capacitor interconnection 28 is not provided over the semiconductor region 26A forming the FD region of the pixel 20A. Thereby, the parasitic capacitor formed by the semiconductor region 26B and the additional capacitor interconnection 28 is connected in parallel to the FD region, which allows the FD capacitance value CfdB to be greater than the FD capacitance value CfdA. The additional capacitor interconnection 28 may be floating or may be connected to a fixed potential. Alternatively, the additional capacitor interconnection 28 may be a drive signal line. Further, the additional capacitor interconnection 28 may be wired so as to bridge over a plurality of pixels 20.

Note that, while the area of the semiconductor region 26A and the area of the semiconductor region 26B are the same as each other in the example of FIG. 5, they are not necessarily required to be the same as long as the relationship between the FD capacitance value CfdA and the FD capacitance value CfdB is maintained. For example, in a similar manner to the example of FIG. 3, the area of the semiconductor region 26A may be greater than the area of the semiconductor region 26B. Further, in a similar manner to the example of FIG. 4, the impurity concentration of the semiconductor region 26B may be higher than the impurity concentration of the semiconductor region 26A.

Next, a failure detection method in the solid-state imaging device according to the present embodiment will be described by using FIG. 6. Note that failure detection of the solid-state imaging device may be performed in a digital front end (DFE) within the solid-state imaging device after a pixel signal is converted into a digital signal inside the solid-state imaging device or may be performed outside the solid-state imaging device. Alternatively, an analog signal may be output from the solid-state imaging device, and failure determination may be performed outside the solid-state imaging device.

FIG. 6 is a diagram illustrating changes in the potential of the FD region in a process of readout of a signal from the pixel 20B. FIG. 6 schematically illustrates a view of changes in the potential of the FD region caused by a voltage being supplied from the voltage supply line 19 to the FD region in a reset state.

In a signal output from the pixel 20B, an output voltage resulted when a CDS process is performed based on a reset signal when the FD region is in a reset state and an output signal when a predetermined fixed potential is supplied to the FD region from the voltage supply line 19 is denoted as a voltage V1. Further, an output voltage resulted when a CDS process is performed based on a reset signal when the FD region is in a reset state and an output signal when no fixed voltage is supplied to the FD region from the voltage supply line 19 (that is, an output signal of the same level as the reset signal) is denoted as a voltage V2. A determination threshold voltage that is a reference in failure determination is set to a voltage near the middle of the voltage V1 and the voltage V2. For example, when the reset voltage is 2.8 V and the fixed voltage is 1.6 V, the voltage V1 is 1.2 V and the voltage V2 is 0 V provided that the conditions are ideal. Thus, the determination threshold voltage is set to 0.6 V that is the intermediate value of the voltage V1 and the voltage V2. If the voltage obtained after the fixed voltage is input exceeds the determination threshold voltage, it is determined that there is no failure, and if not, it is determined that there is a failure.

The failure determination is performed by determining whether or not the voltage V1 exceeds the determination threshold voltage in the pixel 20B supplying a predetermined constant voltage. That is, it is determined that there is a failure if the voltage V1 does not exceed the determination threshold voltage, and it is determined that there is no failure if the voltage V1 exceeds the determination threshold voltage. In describing by using the above-described example, when the value of the voltage V1 is 0.2 V as a result of a CDS process performed after a fixed voltage is input, since the voltage V1 does not exceed the determination threshold voltage, it is determined that there is a failure. On the other hand, when the value of the voltage V1 is 1.0 V, since the voltage V1 exceeds the determination threshold voltage, it is determined that there is no failure. Since the output signal from the pixel 20B is output through the same transmission path as the output signal from the pixel 20A, when it is determined that there is a failure, it can be estimated that there is a failure in the transmission path of the output signal or otherwise the pixel control line 16 or the like.

When the conditions are ideal in a case where the pixel 20B is failed, the voltage V2 is substantially 0 V, and the voltage V2 cannot exceed the determination threshold voltage. However, the potential of the FD region may change due to a noise or a pixel defect occurring on the FD region. For example, when charges flow in the FD region due to occurrence of a thermal noise generated on the FD region or a lead current caused by an electric field with the FD region being floating, the potential of the FD region may decrease. When such a phenomenon occurs, the voltage V2 may become a finite value that is not zero and exceed the determination threshold voltage, which may cause determination that a pixel is normal. For example, in the above-described example, when the value of the voltage V2 is 0.7 V due to the influence of a noise or the like, the voltage V2 exceeds the determination threshold voltage 0.6 V, which may cause a case of determination that there is no failure.

In terms of the above, in the solid-state imaging device according to the present embodiment, the capacitance value of the capacitance component of the FD region of the pixel 20B (FD capacitance value CfdB) is set greater than the capacitance value of the capacitance component of the FD region of the pixel 20A (FD capacitance value CfdA).

A greater value of the FD capacitance value Cfd results in a smaller change ratio of the potential with respect to the amount of charges on the FD region. That is, a greater value of the FD capacitance value Cfd results in a smaller amplification factor of the amplifier unit whose FD region is the input node. That is, the amplification factor of the amplifier unit of the pixel 20A is greater than the amplification factor of the amplifier unit of the pixel 20B.

The potential variation ΔVfd of the FD region is expressed as follows:

ΔVfd=ΔQ/Cfd

where the charge variation on the FD region is denoted as ΔQ, and the FD capacitance value is denoted as Cfd. That is, a greater FD capacitance value Cfd allows for a reduction in the potential variation ΔVfd of the FD region due to the charge variation ΔQ on the FD region.

Therefore, with the above-described relationship of the FD capacitance value CfdA and the FD capacitance value CfdB, it is possible to reduce the change in the potential variation ΔVfd due to the charge variation ΔQ caused by a noise or a pixel defect occurring on the FD region in the pixel 20B. As a result, it is possible to reduce a failure determination error due to the output variation of the pixels 20B used for failure detection and improve the detection accuracy in the failure detection.

Note that an increase of the FD capacitance value Cfd in the pixel 20A used for image acquisition means a decrease in the sensitivity, which are not preferable for the image quality. In terms of improvement of the failure detection accuracy without causing a reduction in the sensitivity of the pixel 20A used for image acquisition, it is desirable to selectively increase the FD capacitance value CfdB of the FD capacitance value CfdA and the FD capacitance value CfdB. It is desirable to separately set the values of the FD capacitance CfdA and the FD capacitance CfdB in accordance with characteristics required to the pixel 20A and the pixel 20B.

A signal based on the amount of charges on the FD region of the pixel 20B is amplified by the amplifier transistor M3B and the column amplifier circuit 42B. It is further desirable to set the FD capacitance value CfdB so as to satisfy the following relationship between the potential variation ΔVfd of the FD region and the determination threshold voltage:

Determination threshold voltage>ΔVfd×A

where the amplification factor of the amplifier unit including the amplifier transistor M3B and the column amplifier circuit 42B is collectively denoted as A.

Since the potential variation ΔVfd is expressed by ΔQ/CfdB×A, this equation can be rewritten as follows:

Determination threshold voltage>ΔQ/CfdB×A

With the FD capacitance value CfdB of the pixel 20B being set as above, even when a potential change of the FD region occurs due to a noise or a pixel defect occurring on the FD region and then further amplified, the amplified value does not exceed the failure determination level, and it is thus possible to reduce the failure determination error. This can further improve the detection accuracy in the failure detection.

As discussed above, according to the present embodiment, it is possible to reduce a failure determination error due to the output variation of the pixels used for failure detection and improve the detection accuracy in the failure detection.

### Second Embodiment

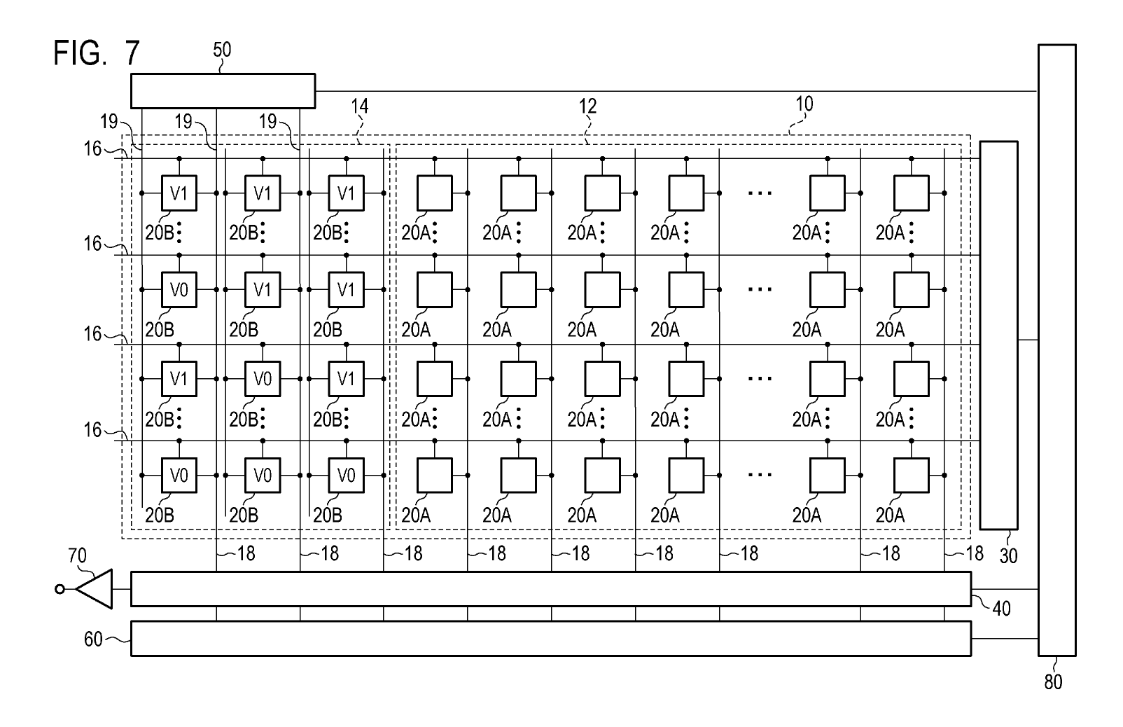

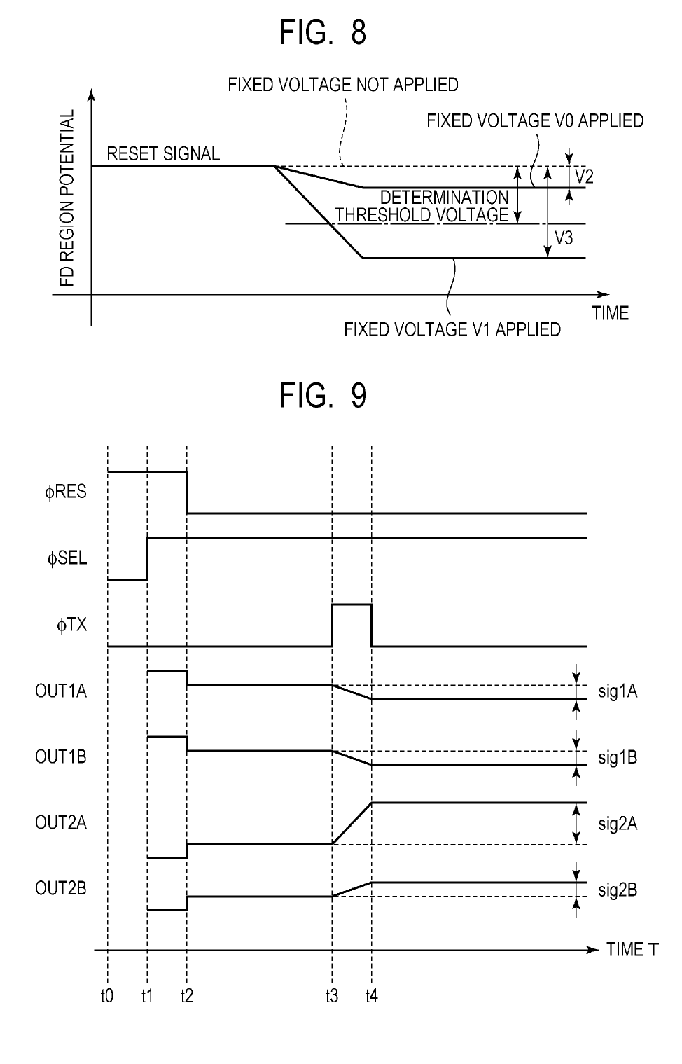

A solid-state imaging device according to a second embodiment of the present invention will be described with reference to FIG. 7 and FIG. 8. The same components as those of the solid-state imaging device of the first embodiment are labeled with the same reference symbol, and the description thereof will be omitted or simplified. FIG. 7 is a diagram illustrating a general configuration of the solid-state imaging device according to the present embodiment. FIG. 8 is a diagram illustrating a failure detection method in the solid-state imaging device according to the present embodiment.

The solid-state imaging device according to the present embodiment is the same as the solid-state imaging device according to the first embodiment except that it is configured to be able to supply two types of constant voltages to the pixels 20B arranged in the second region 14 from the voltage supply unit 50.

In the second region 14, as illustrated in FIG. 7, for example, the pixels 20B supplied with a constant voltage V0 (denoted as “V0” in FIG. 7) and the pixels 20B supplied with a constant voltage V1 (denoted as “V1” in FIG. 7) that is different from the constant voltage V0 are arranged in a matrix according to a particular pattern.

In providing description as an example in which the second region 14 is formed of three columns, the pixels 20B supplied with the constant voltage V0 are arranged on respective columns on one row (for example, the bottom row in FIG. 7), for example. Further, on another row (for example, the second row from the bottom in FIG. 7), the pixel 20B supplied with the constant voltage V1, the pixels 20B supplied with the constant voltage V0, and the pixel 20B supplied with the constant voltage V1 are arranged. That is, the constant voltage pattern applied to the pixels 20B is different depending on the row of the pixel array unit 10.

The pixels 20B used for failure detection and the pixels 20A used for image acquisition belonging to the same row share the pixel control line 16. Therefore, by collating a pattern of the output from the pixels 20B of the second region 14 with an expected value, it is possible to detect whether the vertical scanning circuit 30 is normally operating or is scanning a row different from the expected row due to a failure.

Note that, although the case where the second region 14 is formed of three columns is illustrated as an example in the present embodiment, the number of columns forming the second region 14 is not limited to three.

Next, a failure detection method in the solid-state imaging device according to the present embodiment will be described by using FIG. 8.

FIG. 8 is a diagram illustrating changes in the potential of the FD region in a process of readout of a signal from the pixel 20B. FIG. 8 schematically illustrates a view of changes in the potential of the FD region caused by a voltage being supplied from the voltage supply line 19 to the FD region in a reset state.

In the pixel 20B supplied with the constant voltage V0, an output voltage resulted when a CDS process is performed based on a reset signal when the FD region is in a reset state and an output signal when a predetermined fixed potential is supplied to the FD region from the voltage supply line 19 is denoted as a voltage V2. In the pixel 20B supplied with the constant voltage V1, an output voltage resulted when a CDS process is performed based on a reset signal when the FD region is in a reset state and an output signal when a predetermined fixed voltage is supplied to the FD region from the voltage supply line 19 is denoted as a voltage V3. A determination threshold voltage that is a reference in the failure determination is set to a voltage near the middle of the voltage V2 and the voltage V3. For example, when the reset voltage is 2.8 V, the fixed voltage V0 is 2.8 V, and the fixed voltage V1 is 1.6 V, then the voltage V2 is 0 V, and the voltage V3 is 1.2 V, provided that the conditions are ideal. Thus, the determination threshold voltage is set to 0.6 V that is the intermediate value of the voltage V2 and the voltage V3. As a result of a CDS process performed after the fixed voltage V0 is input, if the voltage V2 does not exceed the determination threshold voltage, it is determined that there is no failure. On the other hand, as a result of a CDS process performed after the fixed voltage V1 is input, if the voltage V3 exceeds the determination threshold voltage, it is determined that there is no failure. In such a way, opposite determination as to whether or not there is a failure is resulted depending on the relationship of the voltage V2 and the voltage V3 with respect to the determination threshold voltage.

The failure determination is performed by determining whether or not the voltage V2 or V3 exceeds the determination threshold voltage. That is, it is determined that there is a failure if the voltage V2 exceeds the determination threshold voltage, and it is determined that there is no failure if the voltage V2 does not exceed the determination threshold voltage. In describing using the above example, as a result of a CDS process performed after the fixed voltage V0 is input, when the value of the voltage V2 is 0.5 V, since the voltage V2 does not exceed the determination threshold voltage, it is determined that there is no failure. On the other hand, when the value of the voltage V2 is 0.9 V, since the voltage V2 exceeds the determination threshold voltage, it is determined that there is a failure. Also, it is determined that there is a failure if the voltage V3 does not exceed the determination threshold voltage, and it is determined that there is no failure if the voltage V3 exceeds the determination threshold voltage. In describing using the above example, as a result of a CDS process performed after the fixed voltage V1 is input, when the value of the voltage V3 is 0.9 V, since the voltage V3 exceeds the determination threshold voltage, it is determined that there is no failure. On the other hand, when the value of the voltage V3 is 0.5 V, since the voltage V3 does not exceed the determination threshold voltage, it is determined that there is a failure. Since the output signal from the pixels 20B is output through the same transmission path as the output signal from the pixel 20A, when it is determined that there is a failure, it can be estimated that there is a failure in the transmission path of the output signal or otherwise the pixel control line 16 or the like.

Also in the solid-state imaging device according to the present embodiment, with the FD capacitance value CfdB being greater than the FD capacitance value CfdA, it is possible to reduce a failure determination error due to the output variation of the pixels 20B used for failure detection and improve the detection accuracy in the failure detection.

As discussed above, according to the present embodiment, it is possible to reduce a failure determination error due to the output variation of the pixels used for failure detection and improve the detection accuracy in the failure detection.

### Third Embodiment

A solid-state imaging device according to a third embodiment of the present invention will be described with reference to FIG. 9. The same components as those of the solid-state imaging device of the first and second embodiments are labeled with the same reference symbol, and the description thereof will be omitted or simplified. FIG. 9 is a timing chart illustrating a method of driving the solid-state imaging device according to the present embodiment.

The solid-state imaging device according to the present embodiment is the same as the solid-state imaging device of the first and second embodiments illustrated in FIG. 1, FIG. 2, FIG. 7, and the like in terms of the circuit configuration. Also in the solid-state imaging device according to the present embodiment, in a similar manner to the first and second embodiments, the amplification factor of a signal based on the amount of charges held in the FD region of the pixel 20A is different from the amplification factor of a signal based on the amount of charges held in the FD region of the pixel 20B.

The solid-state imaging device according to the present embodiment is different from those of the first and second embodiment in that the amplification factor of a signal of the pixel 20A and the amplification factor of a signal of the pixel 20B are defined by the amplification factor of the column amplifier circuit 42 rather than the FD capacitance Cfd. That is, in the solid-state imaging device according to the present embodiment, the amplification factor of the column amplifier circuit 42B that amplifies a signal output from the pixel 20B is set to a value smaller than the amplification factor of the column amplifier circuit 42A that amplifies a signal output from the pixel 20A. Note that the amplification factors of the column amplifier circuits 42A and 42B here refer to the amplification factors of the column amplifier circuit 42A and the column amplifier circuit 42B within one period in which a signal from the pixel 20A and a signal from the pixel 20B are output at the same time.

When the amplification factor of the column amplifier circuit 42A increases and the amplification factor of the column amplifier circuit 42B similarly increases in a case of low illuminance or the like, the amplification factor of the potential variation ΔVfd of the FD region will also increase, which is likely to increase the failure determination error.

By employing the above-described configuration of the present embodiment, however, it is possible to set the amplification factor of the column amplifier circuit 42B to a low value even when increasing the amplification factor of the column amplifier circuit 42A in a case of low illuminance. It is therefore possible to reduce a change in the FD potential due to a noise or a pixel defect occurring on the FD region, which allows for a reduction in the failure determination error due to the output variation of the pixels 20B. This can improve the detection accuracy in the failure detection.

Next, a method of driving the solid-state imaging device according to the present embodiment will be described by using FIG. 9. FIG. 9 illustrates the control signal ϕRES for the reset transistors M2A and M2B, the control signal ϕSEL for the select transistors M4A and M4B, and the control signal ϕTX for the transfer transistors M1A and M1B. The corresponding transistors are turned on when these control signals are a high level, and the corresponding transistors are turned off when these controls signals are a low level. Each drive signal is supplied from the vertical scanning circuit 30 under the control of the control unit 80. Further, FIG. 9 illustrates a potential OUT1A of the vertical output line 18A, a potential OUT1B of the vertical output line 18B, a potential OUT2A of the output signal from the column amplifier circuit 42A, and a potential OUT2B of the output signal from the column amplifier circuit 42B.

At the time t0, the control signal ϕRES supplied from the vertical scanning circuit 30 is a high level, and both the reset transistor M2A of the pixel 20A and the reset transistor M2B of the pixel 20B are in an on-state. Thereby, the FD region of the pixel 20A and the FD region of the pixel 20B have been reset to a potential in accordance with a reset voltage supplied from the power source voltage line VDD.

Further, at the time t0, the control signal ϕSEL supplied from the vertical scanning circuit 30 is a low level, and both the select transistor M4A of the pixel 20A and the select transistor M4B of the pixel 20B are in an off-state. Thus, no signal in accordance with the potentials of the FD region of the pixel 20A and the FD region of the pixel 20B is output to the vertical output lines 18A and 18B.

Subsequently, at the time t1, the control signal ϕSEL is transitioned from a low level to a high level, and the select transistor M4A of the pixel 20A and the select transistor M4B of the pixel 20B are turned on. This operation causes the potential OUT1A of the vertical output line 18A to be a potential in accordance with the potential of the FD region of the pixel 20A and causes the potential OUT1B of the vertical output line 18B to be a potential in accordance with the potential of the FD region of the pixel 20B.

Subsequently, at the time t2, the control signal ϕRES is transitioned from a high level to a low level, and the reset transistor M2A of the pixel 20A and the reset transistor M2B of the pixel 20B are turned off. This operation releases the reset of the FD region of the pixel 20A and the FD region of the pixel 20B. At this operation, the potentials OUT1A and OUT1B also decrease by a certain amount due to a reduction in the potentials of the FD region of the pixel 20A and the FD region of the pixel 20B caused by gate-source coupling of the reset transistors M2A and M2B.

Subsequently, in a period from the time t3 to the time t4, the control signal ϕTX supplied from the vertical scanning circuit 30 is transitioned from a low level to a high level, and the transfer transistor M1A of the pixel 20A and the transfer transistor M1B of the pixel 20B are turned on. This operation causes charges accumulated in the photoelectric converter DA of the pixel 20A to be transferred to the FD region and the potential of the FD region to change, and the potential OUT1A of the vertical output line 18A decreases to a potential in accordance with the changed potential of the FD region. The signal amplitude of the output signal at this time is denoted as sig1A. Further, the potential of the FD region of the pixel 20B changes to a potential in accordance with the constant voltage supplied from the voltage supply line 19, and the potential OUT1B of the vertical output line 18B decreases to a potential in accordance with the changed potential of the FD region. The signal amplitude of the output signal at this time is denoted as sig1B.

The signal output to the vertical output line 18A is amplified by the column amplifier circuit 42A, and the potential OUT2A of the output signal from the column amplifier circuit 42A increases to a potential in accordance with the amplification factor of the column amplifier circuit 42A. The signal amplitude of the output signal on and after the time t4 is denoted as sig2A.

Also, the signal output to the vertical output line 18B is amplified by the column amplifier circuit 42B, and the potential OUT2B of the output signal from the column amplifier circuit 42B increases to a potential in accordance with the amplification factor of the column amplifier circuit 42B. The signal amplitude of the output signal on and after the time t4 is denoted as sig2B.

In the solid-state imaging device according to the present embodiment, failure determination is performed based on the signal amplitude sig2B of the output signal of the pixel 20B.

In the solid-state imaging device according to the present embodiment, the amplification factor of the column amplifier circuit 42B is smaller than the amplification factor of the column amplifier circuit 42A. Thus, even when the signal amplitude sig1A of an output signal on the vertical output line 18A and the signal amplitude sig1B on an output signal on the vertical output line 18B are the same as each other, the signal amplitude sig2B is smaller than the signal amplitude sig2A. It is therefore possible to reduce a potential change of the FD region due to a noise or a pixel defect occurring on the FD region, which allows for a reduction in the failure determination error due to the output variation of the pixels 20B. This can improve the detection accuracy in the failure detection.

Note that, while the amplification factor of a signal of the pixel 20A and the amplification factor of a signal of the pixel 20B are defined by using only the amplification factors of the column amplifier circuits 42A and 42B in the present embodiment, they may be defined by using a combination of the FD capacitance values CfdA and CfdB. The method of defining the amplification factor by using the FD capacitance values CfdA and CfdB has been described in the first embodiment.

As discussed above, according to the present embodiment, it is possible to reduce a failure determination error due to the output variation of the pixels used for failure detection and improve the detection accuracy in the failure detection.

### Fourth Embodiment

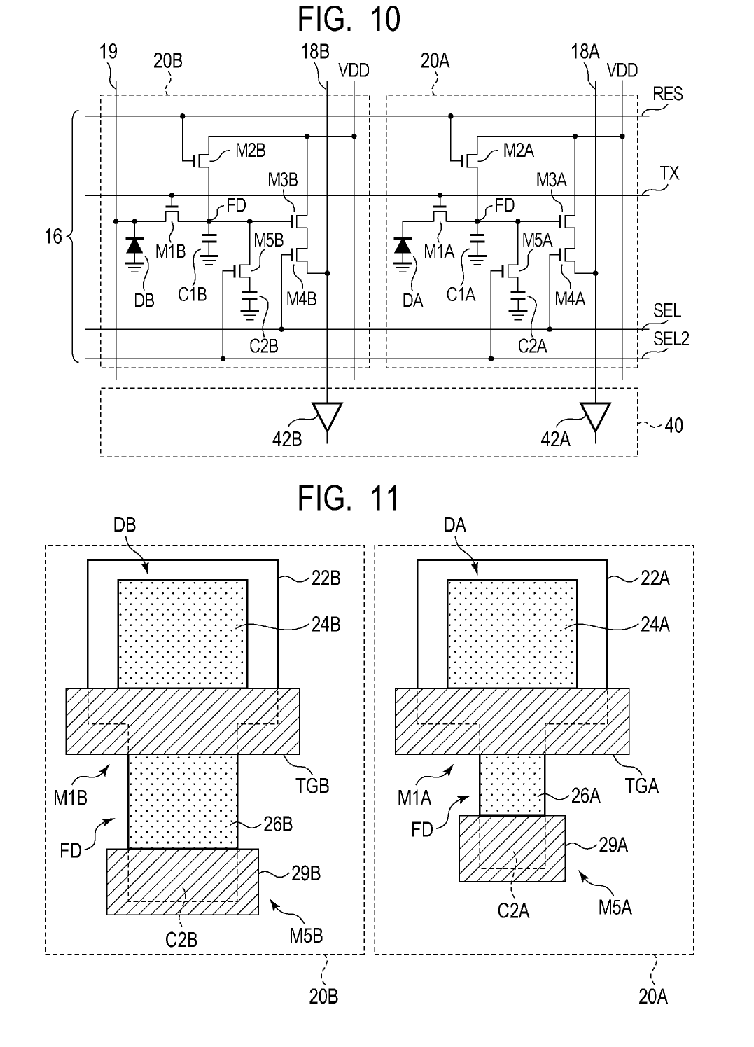

A solid-state imaging device according to a fourth embodiment of the present invention will be described with reference to FIG. 10 and FIG. 11. The same components as those of the solid-state imaging device of the first to third embodiments are labeled with the same reference symbol, and the description thereof will be omitted or simplified.

FIG. 10 is an equivalent circuit diagram of pixels of the solid-state imaging device according to the present embodiment. FIG. 11 is a diagram illustrating a planar layout of the pixels of the solid-state imaging device according to the present embodiment.

The solid-state imaging device according to the present embodiment is different from the solid-state imaging device according to the first to third embodiments in the circuit configuration of the pixels 20A and 20B. That is, the pixel 20A of the solid-state imaging device according to the present embodiment is different from the pixel 20A illustrated in FIG. 2 in that it further includes a capacitor addition transistor M5A and an additional capacitor C2A as illustrated in FIG. 10. Similarly, the pixel 20B of the solid-state imaging device according to the present embodiment is different from the pixel 20B illustrated in FIG. 2 in that it further includes a capacitor addition transistor M5B and an additional capacitor C2B as illustrated in FIG. 10. Other configurations of the solid-state imaging device according to the present embodiment are the same as those in the first to third embodiments.

The additional capacitor C2A is connected to the FD region of the pixel 20A via the capacitor addition transistor M5A. The additional capacitor C2B is connected to the FD region of the pixel 20B via the capacitor addition transistor M5B. The capacitor addition transistor M5A of the pixel 20A and the capacitor addition transistor M5B of the pixel 20B arranged on the same row are connected to a common capacitor addition transistor control line SEL2 and simultaneously controlled by a control signal supplied from the vertical scanning circuit 30.

FIG. 11 is a plan view illustrating an example of the planar layout of the pixel 20A and the pixel 20B for implementing the pixel circuit of FIG. 10.

The semiconductor region 26A forming the FD region of the pixel 20A is arranged between the gate electrode TGA of the transfer transistor M1A and a gate electrode 29A of the capacitor addition transistor M5A. The active region 22A in which the semiconductor region 26A is provided extends under the gate electrode 29A of the capacitor addition transistor M5A to form the additional capacitor C2A between the active region 22A and the gate electrode of the capacitor addition transistor M5A. With such a configuration, connection or disconnection of the additional capacitor C2A to the FD region of the pixel 20A can be controlled by the capacitor addition transistor M5A.

Similarly, the semiconductor region 26B forming the FD region of the pixel 20B is arranged between the gate electrode TGB of the transfer transistor M1B and a gate electrode 29B of the capacitor addition transistor M5B. The active region 22B in which the semiconductor region 26B is provided extends under the gate electrode 29B of the capacitor addition transistor M5B to form the additional capacitor C2B with respect to the gate electrode of the capacitor addition transistor M5B. With such a configuration, connection or disconnection of the additional capacitor C2B to the FD region of the pixel 20B can be controlled by the capacitor addition transistor M5B.

The additional capacitor C2B has a greater capacitance value than the additional capacitor C2A. For example, in the example of FIG. 11, the area of the additional capacitor C2B is larger than the area of the additional capacitor C2A, and thereby the capacitance value of the additional capacitor C2B is greater than the capacitance value of the additional capacitor C2A. With such a configuration, the FD capacitance value when the additional capacitor C2B is added to the FD region of the pixel 20B (CfdB=C1B+C2B) can be greater than the FD capacitance value when the additional capacitor C2A is added to the FD region of the pixel 20A (CfdA=C1A+C2A).

Therefore, also in the solid-state imaging device according to the present embodiment, it is possible to reduce the FD potential change due to a noise or a pixel defect occurring on the FD region of the pixels 20B and improve the detection accuracy in the failure detection.

Note that, while the example in which the additional capacitor C2A is connected via the capacitor addition transistor M5A and the additional capacitor C2B is connected via the capacitor addition transistor M5B has been illustrated in the present embodiment, the capacitor addition transistors M5A and M5B are not necessarily required to be provided. Further, the additional capacitors C2A and C2B and the capacitor addition transistors M5A and M5B or otherwise the additional capacitors C2A and C2B are not necessarily required to be provided to both the pixels 20A and 20B but may be provided to only the pixel 20B. Further, while FIG. 11 illustrates the example in which the area (capacitance value) of the capacitor C1A of the pixel 20A is different from the area (capacitance value) of the capacitor C1B of the pixel 20B, the area (capacitance value) of the capacitor C1A of the pixel 20A may be the same as the area (capacitance value) of the capacitor C1B of the pixel 20B.

As discussed above, according to the present embodiment, it is possible to reduce a failure determination error due to the output variation of the pixels used for failure detection and improve the detection accuracy in the failure detection.

### Fifth Embodiment

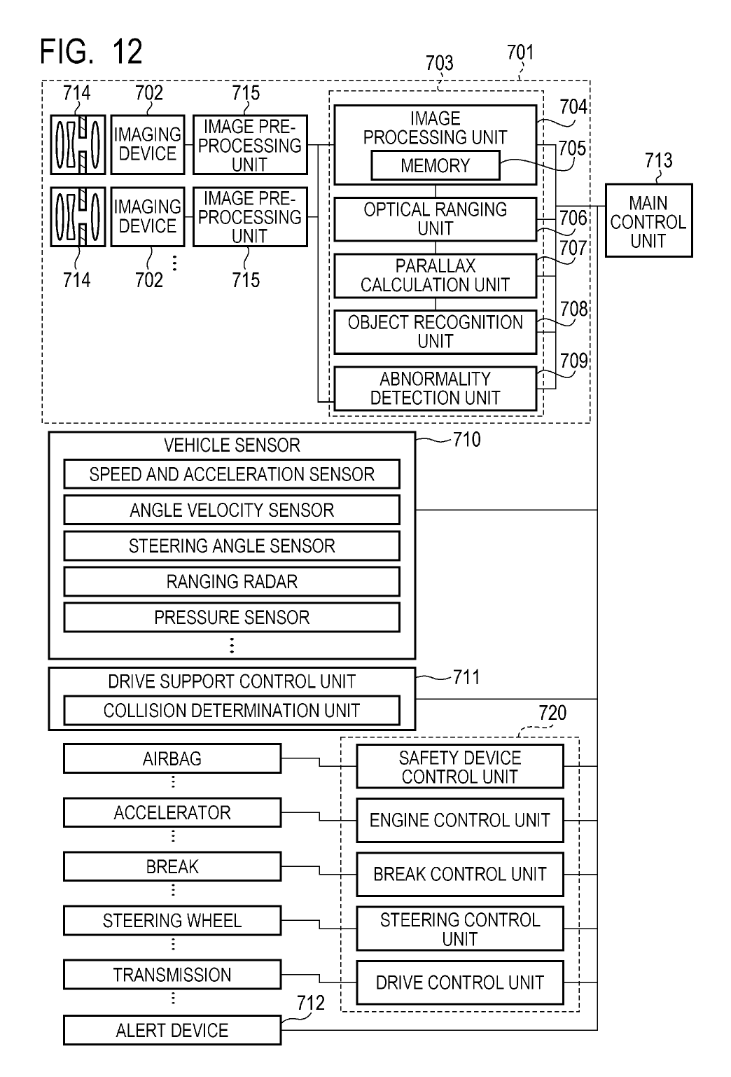

An imaging system and a movable object according to the fifth embodiment of the present invention will be described by using FIG. 12 to FIG. 14.

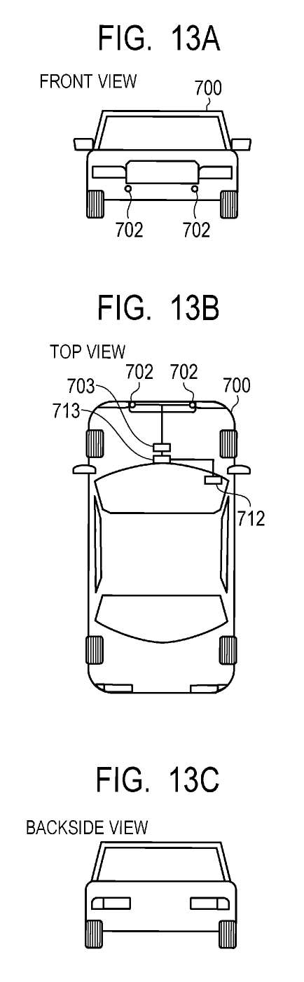

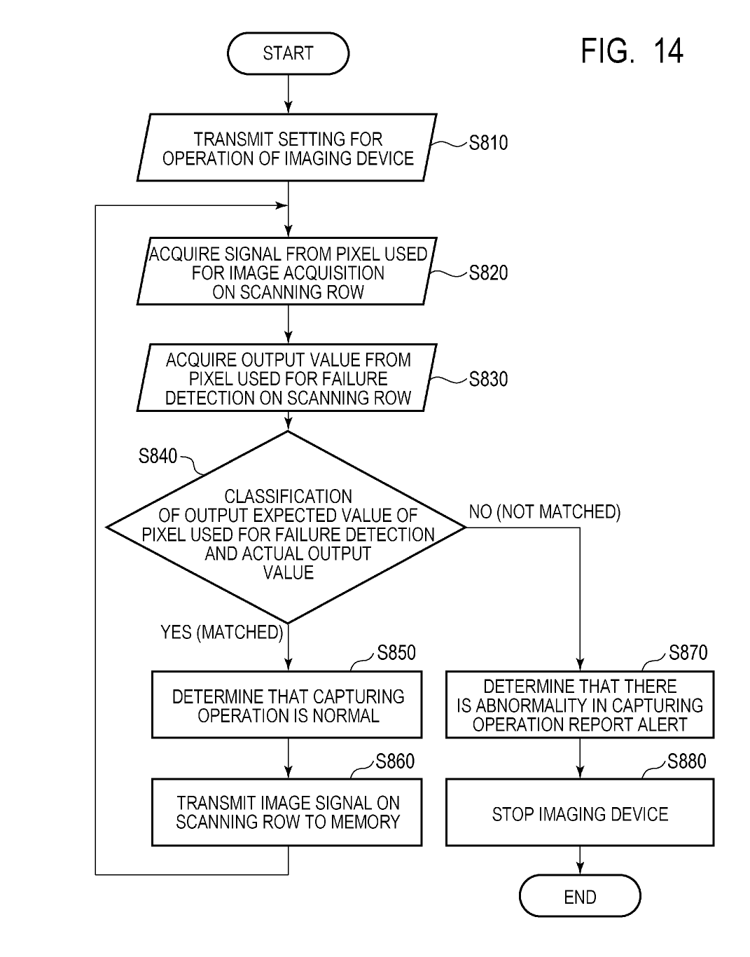

FIG. 12 is a schematic diagram illustrating an example configuration of the imaging system according to the present embodiment. FIG. 13A to FIG. 13C are schematic diagrams illustrating an example configuration of the imaging system and the movable object according to the present embodiment. FIG. 14 is a flow diagram illustrating an operation of the imaging system according to the present embodiment.

In the present embodiment, an example of an imaging system regarding an on-vehicle camera will be illustrated. FIG. 12 illustrates an example of a vehicle system and the imaging system mounted thereon. The imaging system 701 includes imaging devices 702, image pre-processing units 715, an integrated circuit 703, and optical systems 714. Each of the optical systems 714 captures an optical image of a subject onto the corresponding imaging device 702. Each of the imaging devices 702 converts an optical image of a subject captured by the optical system 714 into an electric signal. Each of the imaging devices 702 is the solid-state imaging device of any of the first to fourth embodiments described above. Each of the image pre-processing units 715 performs predetermined signal processing on a signal output from the corresponding imaging device 702. The function of the image pre-processing unit 715 may be embedded inside the imaging device 702. At least two sets of the optical system 714, the imaging device 702, and the image pre-processing unit 715 are included in the imaging system 701, and the output from the image pre-processing unit 715 of each set is input to the integrated circuit 703.

The integrated circuit 703 is an integrated circuit that is specific to an imaging system application and includes an image processing unit 704 including a memory 705, an optical ranging unit 706, a parallax calculation unit 707, an object recognition unit 708, and an abnormality detection unit 709. The image processing unit 704 performs a development process or image processing such as defect correction on the output signals from the image pre-processing units 715. The memory 705 stores primary storage of a captured image or a defect position of the captured image. The optical ranging unit 706 performs focusing or ranging of a subject. The parallax calculation unit 707 calculates a parallax (a phase difference of parallax images) from a plurality of image data acquired by the plurality of imaging devices 702. The object recognition unit 708 performs recognition of a subject such as an automobile, a road, a traffic sign, a person, or the like. When detecting an abnormality of the imaging device 702, the abnormality detection unit 709 reports an abnormality to the main control unit 713.

The integrated circuit 703 may be implemented by dedicatedly designed hardware, may be implemented by a software module, or may be implemented by a combination thereof. Further, the integrated circuit 703 may be implemented by a field programmable gate array (FPGA), an application specific integrated circuit (ASIC), or the like or may be implemented by a combination thereof.

The main control unit 713 coordinates and controls the operation of the imaging system 701, the vehicle sensor 710, the control unit 720, and the like. Note that a scheme (for example, the CAN specification) may be employed in which the main control unit 713 is not provided and the imaging system 701, the vehicle sensor 710, and the control unit 720 have individual communication interfaces and transmit and receive control signals via a communication network, respectively.

The integrated circuit 703 has a function of receiving a control signal from the main control unit 713 or transmitting a control signal or a setting value to the imaging devices 702 by using the control unit of the integrated circuit 703. For example, the integrated circuit 703 transmits setting used for pulse drive of a voltage switch within the imaging device 702, setting used for switching the voltage switch on a frame basis, or the like.

The imaging system 701 is connected to the vehicle sensor 710 and can sense a vehicle traveling state such as a vehicle speed, a yaw rate, a steering angle, or the like and the environment outside the vehicle or a state of another vehicle or an obstacle. The vehicle sensor 710 also serves as a distance information acquisition unit adapted to acquire, from a parallax image, distance information on the distance to an object. Further, the imaging system 701 is connected to a drive support control unit 711 that performs various drive support such as steering, traveling, or collision avoidance function. In particular, for a collision determination function, collision estimation or collision determination with respect to another vehicle or an obstacle is performed based on the sensing result of the imaging system 701 or the vehicle sensor 710. Thereby, avoidance control when a collision is expected or triggering of a safety device at a collision is performed.

Further, the imaging system 701 is connected to the alert device 712 that reports an alert to a driver based on a determination result in the collision determination unit. For example, when the collision possibility is high as a determination result of the collision determination unit, the main control unit 713 performs vehicle control to avoid a collision or reduce damage by applying a brake, pushing back an accelerator, suppressing engine power, or the like. The alert device 712 alerts a user by sounding an alert such as a sound, displaying alert information on a display unit of a car navigation system, a meter panel, or the like, providing vibration to a seat belt or a steering wheel, or the like.

In the present embodiment, an area around the vehicle, for example, an area in front or back of the vehicle is captured by the imaging system 701. FIG. 13A to FIG. 13C illustrate an example arrangement of the imaging system 701 when the area in front of the vehicle is captured by the imaging system 701. FIG. 13A is a front view of the vehicle 700, FIG. 13B is a top view of the vehicle 700, and FIG. 13C is a backside view of the vehicle 700.

The two imaging devices 702 are arranged in the front part of the vehicle 700. Specifically, the center line with respect to the traveling direction or the outer shape (for example, the vehicle width) of the vehicle 700 is defined as a symmetry axis, and the two imaging devices 702 are arranged symmetrically with respect to the symmetry axis, which is preferable in acquiring distance information of the distance between the vehicle 700 and the subject or determining the collision possibility. Further, the imaging device 702 is preferably arranged so as not to block a field of view of a driver when the driver views circumstances outside the vehicle 700 from the driver seat. The alert device 712 is preferably arranged so as to be easily viewed by the driver.

Next, a failure detection operation of the imaging device 702 in the imaging system 701 will be described by using FIG. 14. The failure detection operation of the imaging device 702 is performed according to steps S801 to S880 illustrated in FIG. 14.

Step S801 is a step of performing setting at startup of the imaging device 702. That is, setting for operation of the imaging device 702 is transmitted from the outside of the imaging system 701 (for example, the main control unit 713) or the inside of the imaging system 701 to start a capturing operation and failure detection operation of the imaging device 702.

Subsequently, in step S820, a signal from the pixels 20A of the first region 12 belonging to a scan row is acquired. Further, in step S830, an output value from the pixels 20B of the second region 14 belonging to the scan row is acquired. Note that the order of step S802 and step S830 may be opposite.

Subsequently, in step S840, classification of an output expected value of the pixel 20B and the actual output value is performed. The output expected value here is a value which satisfies a predetermined relationship to a predetermined determination threshold. For example, when the solid-state imaging device according to the first embodiment is used as the imaging device 702, it is determined that the output expected value of the pixel 20B and the actual output value are matched if the voltage V2 output from the pixel 20B is less than or equal to the determination threshold voltage. When the solid-state imaging device according to the second embodiment is used as the imaging device 702, classification of the output expected values of the pixel 20B based on the connection setting of the constant voltages V0 and V1 to the pixel 20B and the actual output value from the pixel 20B may be performed.

As a result of the classification in step S840, if the output expected value and the actual output value are matched, the process enters step S850 to determine that the capturing operation is normally performed and then enters step S860. In step S860, the pixel signal of the scan row is transmitted to and temporarily stored in the memory 705. Then, the process returns to step S820 to continue the failure detection operation.

On the other hand, as a result of the classification in step S840, if the output expected value and the actual output value are not matched, the process enters step S870 to determine that there is an abnormality in the capturing operation and report an alert to the main control unit 713 and the alert device 712. The alert device 712 displays, on the display unit, that an abnormality is detected. Then, the imaging device 702 is stopped in step S880 to terminate the operation of the imaging system 701.

Note that, although the example where a flowchart is looped on a row basis is illustrated in the present embodiment, the flowchart may be looped on a multiple-row basis, or the failure detection operation may be performed on a frame basis.

Further, although the control not to collide with another object has been described in the present embodiment, the present embodiment can be applied to drive control to follow another vehicle, drive control not to go out of a traffic lane, or the like. Furthermore, the imaging system 701 can be applied to a movable object (moving apparatus) such as a ship, an airplane, or an industrial robot, for example, without being limited to a vehicle such as an automobile. In addition, the imaging system 701 can be widely applied to any device which utilizes object recognition, such as an intelligent transportation system (ITS), without being limited to a movable object.

### Modified Embodiments

The present invention is not limited to the above-described embodiments, but various modifications are possible.

For example, the embodiment of the present invention includes an example in which a part of the configuration of any of the embodiments is added to another embodiment or an example in which a part of the configuration of any of the embodiments is replaced with a part of the configuration of another embodiment.

Further, while the above embodiments have been described assuming the case where the transistors of the pixels 20A and 20B are formed of n-channel transistors, the transistors of the pixels 20A and 20B may be formed of p-channel transistors. In this case, the signal level of each drive signal in the above description is inverted.

Further, the imaging system illustrated in the fifth embodiment has been illustrated as an example of imaging systems to which the solid-state imaging device of the present invention can be applied, and the imaging system to which the solid-state imaging device of the present invention can be applied are not limited to the configurations illustrated in FIG. 12 to FIG. 14. For example, the solid-state imaging devices described in the above first to fourth embodiments can be applied to a digital still camera, a digital camcorder, a surveillance camera, or the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-001667, filed Jan. 10, 2017, which is hereby incorporated by reference herein in its entirety.

What is claimed is:

1. A solid-state imaging device comprising:
a first pixel including a photoelectric converter and a first transistor that transfers charges generated in the photoelectric converter to a first node, wherein the first pixel outputs a first signal based on a voltage of the first node;
a second pixel including a second transistor that supplies a constant voltage to a second node, wherein the second pixel outputs a second signal based on a voltage of the second node; and
a control line connected to the first transistor and the second transistor,
wherein a capacitance value of a capacitance component coupled to the second node is greater than a capacitance value of a capacitance component coupled to the first node.

2. The solid-state imaging device according to claim 1 further comprising:
a first output line connected to the first pixel;
a first amplifier circuit connected to the first output line;
a second output line connected to the second pixel; and
a second amplifier circuit connected to the second output line;
wherein, in a period in which the first signal and the second signal are output, an amplification factor of the second amplifier circuit is less than an amplification factor of the first amplifier circuit.

3. The solid-state imaging device according to claim 2, wherein a value of ΔV×A is smaller than a determination threshold voltage for failure determination, where a voltage variation of the second node is ΔV and an amplification factor of the second signal is A.

4. The solid-state imaging device according to claim 1, wherein an area of a semiconductor region forming the second node is larger than an area of a semiconductor region forming the first node.

5. The solid-state imaging device according to claim 1, wherein an impurity concentration of a semiconductor region forming the second node is greater than an impurity concentration of a semiconductor region forming the first node.

6. The solid-state imaging device according to claim 1 further comprising:
a first additional capacitor connected to the first node; and
a second additional capacitor connected to the second node,
wherein a capacitance value of the second additional capacitor is greater than a capacitance value of the first additional capacitor.

7. The solid-state imaging device according to claim 1, wherein a capacitance value of a parasitic capacitance formed between the second node and an interconnection is greater than a capacitance value of a parasitic capacitance formed between the first node and an interconnection.

8. A solid-state imaging device comprising:
a first pixel including a photoelectric converter and a first transistor that transfers charges generated in the photoelectric converter to a first node, wherein the first pixel outputs a first signal based on a voltage of the first node;
a second pixel including a second transistor that supplies a constant voltage to a second node, wherein the second pixel outputs a second signal based on a voltage of the second node;
a control line connected to the first transistor and the second transistor;
a first amplifier unit that amplifies the first signal; and
a second amplifier unit that amplifies the second signal,
wherein, in a period in which the first signal and the second signal are output, an amplification factor of the second amplifier unit is less than an amplification factor of the first amplifier unit.

9. The solid-state imaging device according to claim 8 further comprising:
a first output line connected to the first pixel; and
a second output line connected to the second pixel;
wherein the first amplifier unit includes a first amplifier circuit connected to the first output line, and
wherein the second amplifier unit includes a second amplifier circuit connected to the second output line.

10. The solid-state imaging device according to claim 8, wherein a capacitance value of a capacitance component coupled the second node is greater than a capacitance value of a capacitance component coupled to the first node.

11. The solid-state imaging device according to claim 8, wherein a value of ΔV×A is smaller than a determination threshold voltage for failure determination, where a voltage variation of the second node is ΔV and an amplification factor of the second signal is A.

12. The solid-state imaging device according to claim 10, wherein an area of a semiconductor region forming the second node is larger than an area of a semiconductor region forming the first node.

13. The solid-state imaging device according to claim 10, wherein an impurity concentration of a semiconductor region forming the second node is greater than an impurity concentration of a semiconductor region forming the first node.

14. The solid-state imaging device according to claim 8 further comprising:
a first additional capacitor connected to the first node; and
a second additional capacitor connected to the second node,
wherein a capacitance value of the second additional capacitor is greater than a capacitance value of the first additional capacitor.

15. The solid-state imaging device according to claim 8, wherein a capacitance value of a parasitic capacitance formed between the second node and an interconnection is greater than a capacitance of a parasitic capacitance formed between the first node and an interconnection.

16. An imaging system comprising:
the solid-state imaging device according to claim 1; and
a signal processing unit that processes signals output from the first pixel and the second pixel of the solid-state imaging device.

17. The imaging system according to claim 16 further comprising: an abnormality detection unit that detects an abnormality of the solid-state imaging device based on the second signal output from the second pixel.

18. A movable object comprising:
the solid-state imaging device according to claim 1;
a distance information acquisition unit configured to acquire distance information on a distance to an object, from a parallax image based on a signal output from the first pixel of the solid-state imaging device; and
a control unit configured to control the movable object based on the distance information.

19. The movable object according to claim 18 further comprising: an abnormality detection unit that detects an abnormality of the solid-state imaging device based on the second signal output from the second pixel of the solid state imaging device.
